(19) United States
(12) Patent Application Publication
(10) Pub. No.: US 2023/0378110 A1
(43) Pub. Date: Nov. 23, 2023

(54) SEMICONDUCTOR DEVICE AND METHOD OF FABRICATING THE SAME

(71) Applicant: Samsung Electronics Co., Ltd., Suwon-si (KR)

(72) Inventors: MINKI KIM, Suwon-si (KR); Seungduk Baek, Suwon-si (KR); Hyuekjae Lee, Suwon-si (KR)

(21) Appl. No.: 18/067,773

(22) Filed: Dec. 19, 2022

(30) Foreign Application Priority Data
May 23, 2022 (KR) 10-2022-0062761

(51) Int. Cl. H01L 23/00; H10B 80/00

(52) U.S. Cl. CPC H01L 24/08; H10B 80/00; H01L 24/03; H01L 24/05; H01L 24/80; H01L 2924/1438; H01L 2924/1431; H01L 2224/0801; H01L 2224/08056; H01L 2224/08055; H01L 2224/0807; H01L 2224/08059; H01L 2224/08058; H01L 2224/08121; H01L 2224/08145; H01L 2224/08225; H01L 2224/05647; H01L 2224/05687; H01L 2224/80895; H01L 2224/80896; H01L 2224/03831; H01L 2224/0384

(57) ABSTRACT

Provided is a semiconductor device including lower and upper structures. The lower structure includes a first substrate, a first pad on the first substrate, and a first insulating layer surrounding the first pad. The upper structure includes a second substrate, a second pad on the second substrate, and a second insulating layer surrounding the second pad. The upper and lower structures contact each other. The first and second pads contact each other. The first and second insulating layers contact each other. The first insulating layer includes a first recess adjacent the first pad, the second insulating layer includes a second recess that is adjacent the second pad and overlaps the first recess, and a cavity is defined by the first recess and the second recess, and particles of a metallic material constituting the first and second pads are in the cavity.

### CROSS-REFERENCE TO RELATED APPLICATION

This U.S. non-provisional patent application claims priority under 35 U.S.C. § 119 to Korean Patent Application No. 10-2022-0062761, filed on May 23, 2022, in the Korean Intellectual Property Office, the entire contents of which are hereby incorporated by reference.

### BACKGROUND OF THE INVENTION

The present inventive concept generally relates to a semiconductor device and a method of fabricating the same and, more particularly, to a directly bonded semiconductor device and a method of fabricating the same.

In a semiconductor industry, as demand for high capacity, thinness, and miniaturization of a semiconductor device and an electronic product using the same increases, various package technologies related thereto have emerged. One of them is a package technology that is capable of implementing high-density chip by vertically stacking several semiconductor chips. The package technology may integrate semiconductor chips with various functions in a smaller area than a general package including of a single semiconductor chip.

A semiconductor package is implemented in a form suitable for use in an electronic product as an integrated circuit chip. In general, in the semiconductor package, a semiconductor chip is mounted on a printed circuit board and is electrically connected thereto using bonding wires or bumps. With development of the electronics industry, various studies have been conducted to improve reliability and durability of the semiconductor package.

### SUMMARY

An embodiment of the present inventive concept provides a semiconductor device with improved electrical characteristics and driving stability, and a method of fabricating the same.

An embodiment of the present inventive concept provides a method of fabricating a semiconductor device including less defects and a semiconductor device manufactured therethrough.

A semiconductor device according to embodiments of the present inventive concept may include a lower structure and an upper structure. The lower structure may include a first semiconductor substrate, a first pad on the first semiconductor substrate, and a first insulating layer extending around (e.g., surrounding) the first pad on the first semiconductor substrate. The upper structure may include a second semiconductor substrate, a second pad on the second semiconductor substrate, and a second insulating layer extending around (e.g., surrounding) the second pad on the second semiconductor substrate. The upper structure and the lower structure may contact (e.g., be bonded to) each other such that the first pad and the second pad are in contact with each other and the first insulating layer and the second insulating layer are in contact with each other. The first insulating layer may include a first recess connected to or in contact with the first pad. The second insulating layer may include a second recess connected to or in contact with the second pad and overlapping the first recess. A cavity (e.g., an air gap) may be defined by the first recess and the second recess, and particles of a metallic material constituting the first and second pads may be in the cavity.

A semiconductor device according to embodiments of the present inventive concept may include a lower structure including a first substrate, a first circuit pattern on the first substrate, a first insulating layer on (e.g., covering) the first circuit pattern on the first substrate, and a first pad that includes a metallic material, includes a portion not contacted by the first insulating layer and is electrically connected to the first circuit pattern, an upper structure including a second substrate, a second circuit pattern on the second substrate, a second insulating layer on (e.g., covering) the second circuit pattern on the second substrate, and a second pad that includes the metallic material, includes a portion not contacted by the second insulating layer and is electrically connected to the second circuit pattern, the upper structure contacts or is the vertically connected to the lower structure, and a cavity (e.g., an air gap) extending around (e.g., surrounding) the first pad and the second pad between the first insulating layer and the second insulating layer. The second pad and the first pad may contact (e.g., be bonded to) each other, may constitute an integral one-piece (e.g., a monolithic layer), and may include the same metallic material. An interface between the first insulating layer and the second insulating layer may include a first region extending around (e.g., surrounding) the air gap and a second region extending around (e.g., surrounding) the first region. The first region may be between the cavity and the second region. A concentration of the metallic material in the first region may be less than a concentration of the metallic material in the second region.

A method of fabricating a semiconductor device according to embodiments of the present inventive concept may include providing a lower structure including a first semiconductor substrate, a first pad on the first semiconductor substrate, and a first insulating layer extending around (e.g., surrounding) the first pad on the first semiconductor substrate, forming a first recess extending around (e.g., surrounding) the first pad on the first insulating layer, providing an upper structure including a second semiconductor substrate, a second pad on the second semiconductor substrate, and a second insulating layer extending around (e.g., surrounding) the second pad on the second semiconductor substrate, forming a second recess extending around (e.g., surrounding) the second pad on the second insulating layer, bringing the upper structure and the lower structure into contact such that the first pad and the second pad overlap each other or are vertically aligned and the first insulating layer and the second insulating layer are in contact with each other, and performing a heat treatment process on the upper structure and the lower structure. During the heat treatment process, metallic particles on the first insulating layer or on the second insulating layer may move to the first recess and the second recess.

A semiconductor device according to embodiments of the present inventive concept may include a substrate, a substrate pad on an upper surface of the substrate, a first conductive pattern in contact with a lower surface of the substrate pad, a first insulating layer and a second insulating layer stacked on the substrate, wherein the conductive pattern is in the first insulating layer and the second insulating layer, and a semiconductor chip on the upper surface of the substrate. The semiconductor chip may include a semiconductor substrate, a wiring layer that is on a lower surface of the semiconductor substrate and includes a wiring pattern, and a bonding pad connected to a lower surface of the wiring pattern. The bonding pad may contact (e.g., be directly bonded to) the substrate pad. The first insulating layer may include a first region extending around (e.g., surrounding) the first conductive pattern and a second region surrounding the first region. The first region of the first insulating layer may be spaced apart from the second insulating layer, and the second region of the first insulating layer may be in contact with the second insulating layer. Particles of a metallic material that constitutes the conductive pattern may be between the first region of the first insulating layer and the second insulating layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a semiconductor device according to embodiments of the present inventive concept.

FIGS. 2 and 3 are plan views of a semiconductor device according to embodiments of the present inventive concept.

FIGS. 4 to 8 are enlarged views of the portion “A” of FIG. 1.

FIG. 9 is a cross-sectional view of a semiconductor device according to embodiments of the present inventive concept.

FIG. 10 is a plan view of a semiconductor device according to embodiments of the present inventive concept.

FIG. 11 is an enlarged view of the portion “B” of FIG. 9.

FIG. 12 is a cross-sectional view of a semiconductor device according to embodiments of the present inventive concept.

FIG. 13 is an enlarged view of the portion “C” of FIG. 12.

FIG. 14 is a cross-sectional view of a semiconductor device according to embodiments of the present inventive concept.

FIG. 15 is a plan view of a semiconductor device according to embodiments of the present inventive concept.

FIG. 16 is a cross-sectional view of a semiconductor device according to embodiments of the present inventive concept.

FIGS. 17 to 23 are cross-sectional views for explaining a method of fabricating a semiconductor device according to embodiments of the present inventive concept.

### DETAILED DESCRIPTION

Semiconductor devices according to some embodiments of the present inventive concept will be described with reference to the drawings.

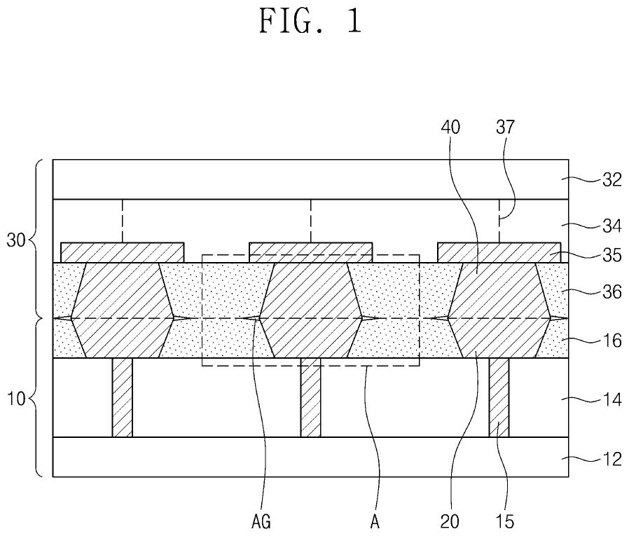

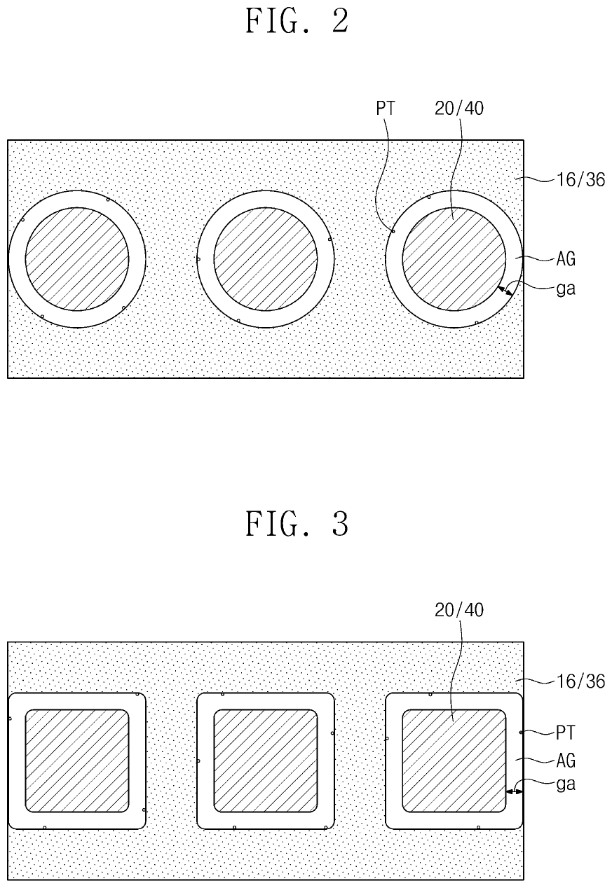

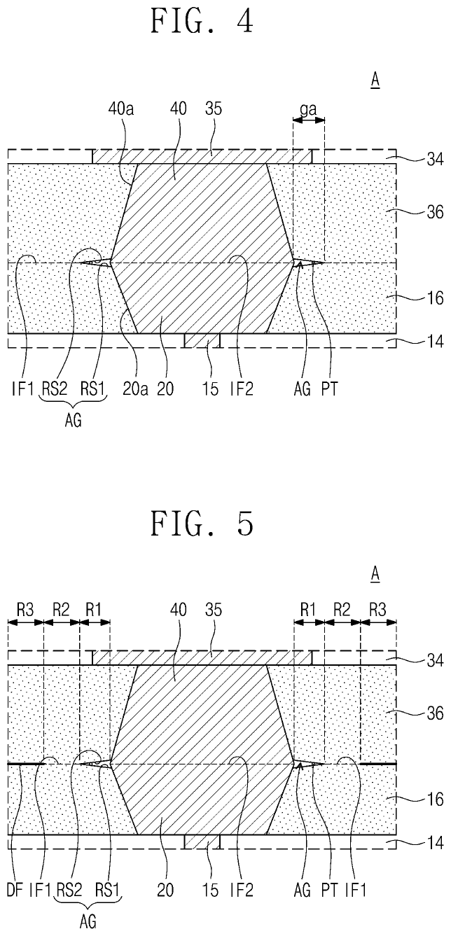

FIG. 1 is a cross-sectional view of a semiconductor device according to embodiments of the present inventive concept. FIGS. 2 and 3 are plan views of a semiconductor device according to embodiments of the present inventive concept. FIGS. 4 to 8 are enlarged views of the portion “A” of FIG. 1.

Referring to FIGS. 1 to 4, a semiconductor device may include a lower structure 10 and an upper structure 30 stacked on the lower structure 10.

The lower structure 10 may include a first substrate 12, a first circuit layer 14, a first insulating layer 16, and first pads 20.

The first substrate 12 may be provided. The first substrate 12 may be a semiconductor substrate such as a semiconductor wafer. The first substrate 12 may be a bulk silicon substrate, a silicon-on-insulator (SOI) substrate, a germanium substrate, a germanium-on-insulator (GOI) substrate, a silicon-germanium substrate, or a substrate of an epitaxial thin film obtained by performing selective epitaxial growth (SEG). The first substrate 12 may include, for example, at least one of silicon (Si), germanium (Ge), silicon germanium (SiGe), gallium arsenide (GaAs), indium gallium arsenide (InGaAs), aluminum gallium arsenide (AlGaAs), or a combination thereof. In some embodiments, the first substrate 12 may be an insulating substrate.

The first circuit layer 14 may be provided on the first substrate 12. The first circuit layer 14 may include a first circuit pattern provided on the first substrate 12 and an insulating layer covering the first circuit pattern. The first circuit pattern may be a memory circuit including one or more transistors, a logic circuit, or a combination thereof. In some embodiments, the first circuit pattern may include a passive element such as a resistor or a capacitor.

The first pads 20 may be disposed on the first circuit layer 14. The first pads 20 may have a damascene structure (e.g., a structure formed by a damascene process). For example, the first pads 20 may further include a seed layer or a barrier layer covering side and lower surfaces thereof. A width of each of the first pads 20 may decrease toward the first substrate 12. Unlike the drawings, the first pads 20 may have a T-shaped cross-section including a via portion and a pad portion on the via portion, which are integrally connected to each other. As shown in FIG. 2, a planar shape of each of the first pads 20 may be circular. In some embodiments, as shown in FIG. 3, the planar shape of each of the first pads 20 may be a quadrangle. However, the present inventive concept is not limited thereto, and the planar shape of each of the first pads 20 may have various shapes as needed. The width of each of the first pads 20 may be 2 um to 30 um. However, the present inventive concept is not limited thereto. The first pads 20 may include metal. For example, the first pads 20 may include copper (Cu).

The first pads 20 may be electrically connected to the first circuit pattern of the first circuit layer 14. For example, as shown in FIG. 1, a first connection wiring 15 may be provided in the first circuit layer 14. The first connection wiring 15 may be a through-via vertically penetrating the insulating pattern in the first circuit layer 14. The first connection wiring 15 may extend vertically in the first circuit layer 14 to be connected to the first pads 20. The first connection wiring 15 may electrically connect the first circuit pattern and the first pads 20. Although not shown in FIG. 1, various conductive patterns for wiring may be provided between the first circuit pattern and the first connection wiring 15. Unlike those shown in FIG. 1, the first connection wiring 15 may be an under pad pattern or a redistribution pattern provided in the insulating pattern of the first circuit layer 14. In this case, various conductive patterns for wiring may be provided between the first circuit pattern and the first connection wiring 15. However, the present inventive concept is not limited thereto, and the first circuit layer 14 may be provided in various forms as needed, and a connection between the first pads 20 and the first circuit layer 14 may be formed through various configurations as necessary.

The first insulating layer 16 may be disposed on the first circuit layer 14. The first insulating layer 16 may surround the first pads 20 on the first circuit layer 14. Upper surfaces of the first pads 20 may be exposed by the first insulating layer 16. An upper surface of the first insulating layer 16 may be coplanar with the upper surfaces of the first pads 20. The first insulating layer 16 may include an oxide, nitride, or oxynitride of a material constituting the first substrate 12 or the first circuit layer 14. The first insulating layer 16 may include an insulating material such as silicon oxide (SiO), silicon nitride (SiN), silicon oxynitride (SiON), or silicon carbonitride (SiCN). Each of the first pads 20 may include a portion that is in the first insulating layer 16. In some embodiments, the entirety of each of the first pads 20 may be in the first insulating layer 16.

First recesses RS1 may be provided on the first insulating layer 16. Each of the first recesses RS1 may surround one first pad 20. That is, when viewed in a plan view, each of the first recesses RS1 may have a planar shape of a ring surrounding each of the first pads 20, respectively. In detail, the planar shape of each of the first recesses RS1 may be larger than the planar shape of each of the first pads 20. For example, an overall width of the first recesses RS1, that is, an outer diameter of each of the first recesses RS1 when viewed from a plan view may be greater than a width of each of the first pads 20. For example, an inner diameter of the first recesses RS1 may be the same as the width of each of the first pads 20, and the first recesses RS1 may be in contact with each of the first pads 20. In some embodiments, the first recesses RS1 may be connected to the first pads 20, respectively. Each of the first recesses RS1 may have the planar shape of a circular ring (refer to FIG. 2) or a tetragonal ring (refer to FIG. 3) depending on the shape of each of the first pads 20. That is, the upper surfaces of the first pads 20 and the upper surface (e.g., a non-tilted portion of the upper surface) of the first insulating layer 16 may be spaced apart from each other by the first recesses RS1. The first recesses RS1 may expand to the first substrate 12 from the upper surface of the first insulating layer 16. In this case, a first depth of each of the first recesses RS1 may decrease as a distance from each of the first pads 20 increases.

The upper structure 30 may include a second substrate 32, a second circuit layer 34, a second insulating layer 36, and second pads 40. The first pad 20 and the second pad 40 may be referred to as a first conductive pattern and a second conductive pattern, respectively. Further, the first pad 20 and the second pad 40 may be collectively referred to as a conductive pattern.

The second substrate 32 may be provided. The second substrate 32 may be a semiconductor substrate such as a semiconductor wafer. The second substrate 32 may be a bulk silicon substrate, a silicon-on-insulator (SOI) substrate, a germanium substrate, a germanium-on-insulator (GOI) substrate, a silicon-germanium substrate, or a substrate of an epitaxial thin film obtained by performing selective epitaxial growth (SEG). The second substrate 32 may include, for example, at least one of silicon (Si), germanium (Ge), silicon germanium (SiGe), gallium arsenide (GaAs), indium gallium arsenide (InGaAs), aluminum gallium arsenide (AlGaAs), or a combination thereof. In some embodiments, the second substrate 32 may be an insulating substrate.

The second circuit layer 34 may be provided on the second substrate 32. The second circuit layer 34 may include a second circuit pattern provided on the second substrate 32 and an insulating layer covering the second circuit pattern. The second circuit pattern may be a memory circuit including one or more transistors, a logic circuit, or a combination thereof. In some embodiments, the second circuit pattern may include a passive element such as a resistor element or a capacitor.

The second pads 40 may be disposed on the second circuit layer 34. The second pads 40 may have a damascene structure (e.g., a structure formed by a damascene process). For example, the second pads 40 may further include a seed layer or a barrier layer covering side and lower surfaces thereof. A width of each of the second pads 40 may decrease toward the second substrate 32. Unlike the drawings, the second pads 40 may have a T-shaped cross-section including a via portion and a pad portion on the via portion, which are integrally connected to each other. As shown in FIG. 2, a planar shape of each of the second pads 40 may be circular. In some embodiments, as shown in FIG. 3, the planar shape of each of the second pads 40 may be a quadrangle. However, the present inventive concept is not limited thereto, and the planar shape of each of the second pads 40 may have various shapes as needed. The planar shape of each of the second pads 40 may be substantially the same as the planar shape of each of the first pads 20. In some embodiments, the planar shape of each of the second pads 40 may be different from the planar shape of each of the first pads 20. A thickness of each of the second pads 40 may be greater than a thickness of each of the first pads 20. However, the present inventive concept is not limited thereto, and the thickness of each of the first pads 20 and the thickness of each of the second pads 40 may be provided in various ways as needed. The width of each of the second pads 40 may be 2 um to 30 um. However, the present inventive concept is not limited thereto. The second pads 40 may include metal. For example, the second pads 40 may include copper (Cu).

The second pads 40 may be electrically connected to the second circuit pattern of the second circuit layer 34. For example, as shown in FIG. 1, a second connection wiring 35 may be provided in the second circuit layer 34. The second connection wiring 35 may be an under pad pattern or a redistribution pattern provided in the insulating pattern of the second circuit layer 34. The second connection wiring 35 may extend vertically in the second circuit layer 34 to be connected to the second pads 40. The second connection wiring 35 may electrically connect the second circuit pattern and the second pads 40. Although conductive patterns 37 are shown by dotted lines in FIG. 1, various conductive patterns 37 for wiring may be provided between the second circuit pattern and the second connection wiring 35. Unlike those illustrated in FIG. 1, the second connection line 35 may be a through-via penetrating the insulating pattern in the second circuit layer 34. However, the present inventive concept is not limited thereto, and the second circuit layer 34 may be provided in various forms as needed, and a connection between the second pads 40 and the second circuit layer 34 may be formed through various configurations as necessary.

The second insulating layer 36 may be disposed on the second circuit layer 34. The second insulating layer 36 may surround the second pads 40 on the second circuit layer 34. Lower surfaces of the second pads 40 may be exposed by the second insulating layer 36. A lower surface of the second insulating layer 36 may be coplanar with the lower surfaces of the second pads 40. The second insulating layer 36 may include an oxide, nitride, or oxynitride of a material constituting the second substrate 32 or the second circuit layer 34. The second insulating layer 36 may include the same material as the first insulating layer 16. The second insulating layer 36 may include an insulating material such as silicon oxide (SiO), silicon nitride (SiN), silicon oxynitride (SiON), or silicon carbonitride (SiCN).

Second recesses RS2 may be provided on the second insulating layer 36. Each of the second recesses RS2 may surround one second pad 40. That is, when viewed in a plan view, each of the second recesses RS2 may have a planar shape of a ring surrounding the each of second pads 40, respectively. In detail, the planar shape of each of the second recesses RS2 may be larger than the planar shape of each of the second pads 40. For example, an overall width of the second recesses RS2, that is, an outer diameter of the second recesses RS2 when viewed from a plan view may be greater than a width of each of the second pads 40. For example, an inner diameter of the second recesses RS2 may be the same as the width of each of the second pads 40, and the second recesses RS2 may be in contact with each of the second pads 40. In some embodiments, the second recesses RS2 may be connected to the second pads 40, respectively. Each of the second recesses RS2 may have a planar shape of a circular ring (refer to FIG. 2) or a tetragonal ring (refer to FIG. 3) depending on the shape of each of the second pads 40. That is, the lower surface of each of the second pads 40 and the lower surface (e.g., a non-tilted portion of the lower surface) of the second insulating layer 36 may be spaced apart from each other by the second recesses RS2. The second recesses RS2 may expand to the second substrate 32 from the lower surface of the second insulating layer 36. In this case, a second depth of each of the second recesses RS2 may decrease as a distance from each of the second pads 40 increases.

The upper structure 30 may be disposed on the lower structure 10. The first pads 20 of the lower structure 10 and the second pads 40 of the upper structure 30 may be vertically aligned. Also, the first recesses RS1 of the lower structure 10 and the second recesses RS2 of the upper structure 30 may be vertically aligned. The lower structure 10 and the upper structure 30 may be in contact with each other such that the first pads 20 and the second pads 40 are connected to each other.

At an interface between the lower structure 10 and the upper structure 30, the first insulating layer 16 of the lower structure 10 and the second insulating layer 36 of the upper structure 30 may be bonded. In this case, the first insulating layer 16 and the second insulating layer 36 may form oxide, nitride, or oxynitride hybrid bonding. As used herein, the hybrid bonding refers to bonding in which two constituents including homogeneous materials are fused at their interface. For example, the first insulating layer 16 and the second insulating layer 36 bonded to each other may have a continuous configuration, and a first interface IF1 between the first insulating layer 16 and the second insulating layer 36 may not be visible. For example, the first insulating layer 16 and the second insulating layer 36 may be formed of the same material, and thus there may be no interface between the first insulating layer 16 and the second insulating layer 36. That is, the first insulating layer 16 and the second insulating layer 36 may be provided as one component. For example, the first insulating layer 16 and the second insulating layer 36 may be combined to form an integral one-piece (e.g., a monolithic or unitary layer). However, the present inventive concept is not limited thereto. The first insulating layer 16 and the second insulating layer 36 may be formed of different materials. The first insulating layer 16 and the second insulating layer 36 may not have a continuous configuration, and the first interface IF1 between the first insulating layer 16 and the second insulating layer 36 may be visible. The first insulating layer 16 and the second insulating layer 36 may not be bonded to each other, and each of the first insulating layer 16 and the second insulating layer 36 may be provided as an individual component. Hereinafter, the description will be continued with reference to the embodiments of FIGS. 1 and 4.

The upper structure 30 may be connected to the lower structure 10. In detail, the lower structure 10 and the upper structure 30 may be in contact with each other. At the interface between the lower structure 10 and the upper structure 30, the first pads 20 of the lower structure 10 and the second pads 40 of the upper structure 30 may be bonded. In this case, the first pads 20 and the second pads 40 may form an intermetallic hybrid bonding, respectively. For example, the first pad 20 and the second pad 40 bonded to each other may have a continuous configuration, and a second interface IF2 may not be visible. For example, the first pads 20 and the second pads 40 may be formed of the same material, and thus there may be no interface between the first pads 20 and the second pads 40. That is, the first pads 20 and the second pads 40 may be provided as one component, respectively. For example, the first pads 20 may be combined with the second pads 40, respectively to form an integral one-piece (e.g., a monolithic or unitary layer).

When a region in which the first recesses RS1 are provided on the first insulating layer 16 is referred to as a first region, and the remaining region surrounding the first region is referred to as a second region, the first insulating layer 16 and the second insulating layer 36 may be spaced apart from each other by the first recesses RS1 and the second recesses RS2 in the first region, and the first insulating layer 16 and the second insulating layer 36 may be in contact with each other in the second region. This will be described in detail below.

As the lower structure 10 and the upper structure 30 are bonded, the first recesses RS1 of the lower structure 10 and the second recesses RS2 of the upper structure 30 may be connected to each other. In detail, the first pads 20 and the second pads 40 may be vertically aligned with each other, and the first recesses RS1 surrounding each of the first pads 20 and the second recesses RS2 surrounding each of the second pads 40 may also be vertically aligned with each other. At the interface between the lower structure 10 and the upper structure 30, the first recesses RS1 and the second recesses RS2 may be in contact with each other, and one first recess RS1 and one second recess RS2 into contact with each other may constitute one air gap AG. That is, the air gaps AG may be empty spaces, each which is defined by the first insulating layer 16, the second insulating layer 36, one first pad 20, and one second pad 40. In some embodiments, the first recesses RS1 may be connected to the second recesses RS2, respectively. The first regions described above may correspond to regions in which the air gaps AG are provided. The uppermost ends of the air gaps AG may be located at a level higher than the first interface IF1 between the first insulating layer 16 and the second insulating layer 36 and the second interface IF2 between the first pads 20 and the second pads 40. The lowermost ends of the air gaps AG may be located at a level lower than the first interface IF1 between the first insulating layer 16 and the second insulating layer 36 and the second interface IF2 between the first pads 20 and the second pads 40. As used herein, “air gap” may be interchangeable with “cavity” or “void” and may refer to a gap filled with air (e.g., an air-gap), a gap filled with an inert gas or gases (e.g., an inert gas gap), a gap defining a vacuum (e.g., a vacuum gap), etc. Further, as used herein, “an element/surface A is lower than an element/surface B” (or similar language) may mean that the element/surface A is closer than the element/surface B to the first substrate 12.

The air gap AG may be provided as the plural, and each of the air gaps AG may surround one first pad 20 and one second pad 40. That is, when viewed in a plan view, each of the air gaps AG may have a planar shape of a ring surrounding the first and second pads 20 and 40, respectively. In detail, the planar shape of each of the air gaps AG may be larger than the planar shape of each of the first pads 20 and the planar shape of each of the second pads 40. For example, an overall width of the air gaps AG, that is, an outer diameter of the air gaps AG when viewed from a plan view may be greater than the width of each of the first pads 20 and the width of the second pads 40. For example, an inner diameter of the air gaps AG may be the same as the width of each of the first pads 20 and the width of each of the second pads 40, and the air gaps AG may be in contact with each of the first pads 20 and each of the second pads 40. The air gaps AG may have the planar shape of a circular ring (refer to FIG. 2) or a tetragonal ring (refer to FIG. 3) depending on the shapes of the first pads 20 and the second pads 40. That is, the first interface IF1 between the first insulating layer 16 and the second insulating layer 36 and the second interface IF2 between the first pads 20 and the second pads 40 may be spaced apart from each other by the air gaps AG. A width of each of the air gaps AG may decrease as a distance from each of the first pads 20 and each of the second pads 40 increases. Here, the width of the each of air gaps AG means a width in a vertical direction of the semiconductor device, that is, in a direction from the first substrate 12 to the second substrate 32. A distance ga from a side surface 20a of the first pads 20 or a side surface 40a each of the second pads 40 to the outermost surface of the air gaps AG may be 0.1 μm to 5 μm. The outermost end of the air gaps AG may correspond to an interface between the first regions and the second regions described above.

Metal particles PT may be disposed in the air gaps AG. One or more metal particles PT may be disposed in each of the air gaps AG. Unlike the illustration, in any one of the air gaps AG, the metal particles PT may not be disposed. The metal particles PT may be disposed adjacent to the outermost ends of the air gaps AG within the air gaps AG. The metal particles PT may be formed of the same metal material as the metal material forming the first pads 20 or the metal material forming the second pads 40. For example, the metal particles PT may include copper (Cu). The metal particles PT may be an aggregate of debris generated from the first pads 20 and the second pads 40 during the fabricating process of the semiconductor device. For example, when the lower structure 10 and the upper structure 30 are bonded, the debris of the first pads 20 and the second pads 40 interposed between the first insulating layer 16 and the second insulating layer 36 may be collected into the air gaps AG to form the metal particles PT. Accordingly, the debris may be absent from the first interface IF1 between the first insulating layer 16 and the second insulating layer 36. For example, a concentration of the metal material at the first interface IF1 between the first insulating layer 16 and the second insulating layer 36 may be substantially zero. Here, the concentration of the metal material at the first interface IF1 means an amount (mass or atomic weight) of the metal material in a unit area of the first interface IF1. As used herein, a metal material refer to a metallic material.

According to embodiments of the present inventive concept, the debris between the first insulating layer 16 and the second insulating layer 36 may be collected into the air gaps AG, and thus the debris may not be provided between the first insulating layer 16 and the second insulating layer 36. There may be no conductive material on the first interface IF1 between the first insulating layer 16 and the second insulating layer 36. In addition, the first interface IF1 or a space between the first insulating layer 16 and the second insulating layer 36 may have high insulation. Accordingly, a short circuit that occurs between the adjacent first and second pads 20 and 40 due to the debris remaining between the first insulating layer 16 and the second insulating layer 36 may be reduced or may not be present. That is, a semiconductor device having improved electrical characteristics and improved driving stability may be provided. The collection of the debris between the first insulating layer 16 and the second insulating layer 36 will be described in detail later along with a method of fabricating the semiconductor device.

In the following embodiments, for convenience of description, detailed descriptions of technical features overlapping those described above with reference to FIGS. 1 to 4 will be omitted, and differences will be described in detail. The same reference numerals may be provided to the same components as those of the semiconductor package according to the above-described embodiments of the present inventive concept.

Unlike those illustrated in FIG. 4, the debris may remain on a partial region of the first interface IF1 between the first insulating layer 16 and the second insulating layer 36.

FIG. 5 is another enlarged view of the portion “A” of FIG. 1.

Referring to FIG. 5, first regions R1, second regions R2, and third regions R3 may be provided at the interface between the lower structure 10 and the upper structure 30.

The first regions R1 may be defined as regions in which the air gaps AG are provided. Each of the first regions R1 may surround each of the first pads 20 and each of the second pads 40 when viewed in a plan view. The second regions R2 may surround the first regions R1, respectively when viewed in a plan view. The third region R3 may be a region remaining at the interface between the lower structure 10 and the upper structure 30, except for the first regions R1 and the second regions R2. That is, the second regions R2 correspond to regions adjacent to the air gaps AG at the first interface IF1 between the first insulating layer 16 and the second insulating layer 36, and the third region R3 may correspond to the remaining region of the first interface IF1 between the first insulating layer 16 and the second insulating layer 36.

A concentration of the metal material in the second regions R2 may be less than a concentration of the metal material in the third region R3. More preferably, the concentration of the metal material in the second regions R2 may be zero. The metal material in the third region R3 may form a debris film DF interposed between the first insulating layer 16 and the second insulating layer 36. The debris film DF may include the metal material constituting the first pads 20 and the second pads 40.

According to embodiments of the present inventive concept, the debris film DF may not be provided between the first insulating layer 16 and the second insulating layer 36 around each of the first pads 20 and each of the second pads 40. That is, a high insulating region free of conductive debris may be provided at the first interface IF1 between the first insulating layer 16 and the second insulating layer 36 adjacent to each of the first pads 20 and each of the second pads 40. Accordingly, a short circuit occurring between the adjacent first pads 20 and the second pads 40 may be reduced or absent. That is, a semiconductor device having improved electrical characteristics and improved driving stability may be provided.

Unlike those illustrated in FIG. 4, one of the first recesses RS1 of the first insulating layer 16 and the second recesses RS2 of the second insulating layer 36 may be provided.

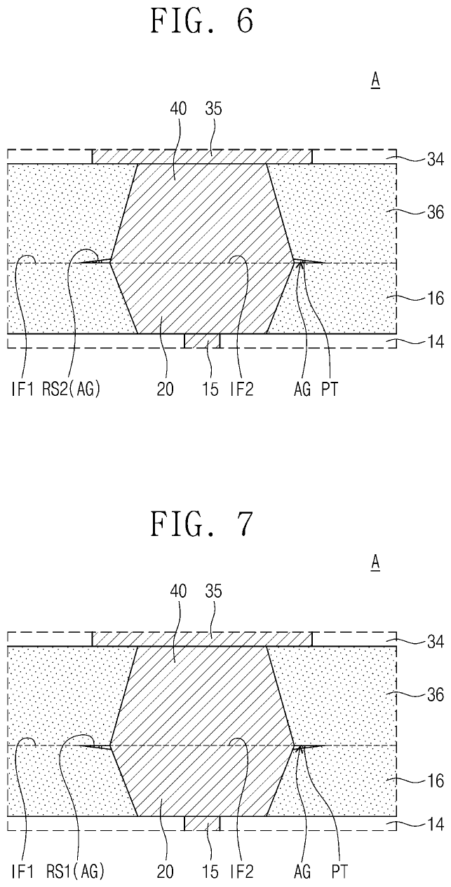

FIGS. 6 and 7 are enlarged views of the portion “A” of FIG. 1.

Referring to FIG. 6, the first recesses RS1 (refer to FIG. 4) may not be provided on the first insulating layer 16. For example, the upper surfaces of the first pads 20 and the upper surfaces of the first insulating layer 16 may be in contact with each other. The first pads 20 and the second pads 40 may be stacked in a vertical direction.

The second recesses RS2 may be provided on the second insulating layer 36. Each of the second recesses RS2 may surround one second pad 40. That is, when viewed in a plan view, each of the second recesses RS2 may have a planar shape of a ring surrounding each of the second pads 40, respectively. Each of the second recesses RS2 may expand to the second substrate 32 from the lower surface of the second insulating layer 36. In this case, the depth (e.g., the depth in the vertical direction) of each of the second recesses RS2 may decrease as the distance from each of the second pads 40 increases.

The upper structure 30 may be disposed on the lower structure 10. The first pads 20 of the lower structure 10 and the second pads 40 of the upper structure 30 may be vertically aligned. In some embodiments, the first pads 20 and the second pads 40 may overlap in the vertical direction, as illustrated in FIG. 6. The lower structure 10 and the upper structure 30 may be in contact with each other such that the first pads 20 and the second pads 40 are connected to each other. As used herein, “an element A vertically overlapping an element B” (or similar language) means that at least one vertical line can be drawn that intersects both elements A and B.

At the interface between the lower structure 10 and the upper structure 30, the first insulating layer 16 of the lower structure 10 and the second insulating layer 36 of the upper structure 30 may be bonded. At the interface between the lower structure 10 and the upper structure 30, the first pads 20 of the lower structure 10 and the second pads 40 of the upper structure 30 may be bonded.

As the lower structure 10 and the upper structure 30 are bonded, the second recesses RS2 of the upper structure 30 may be disposed on the first insulating layer 16 of the lower structure 10. At the interface between the lower structure 10 and the upper structure 30, one second recess RS2 may constitute one air gap AG. That is, the air gaps AG may be empty spaces, each which is defined by the first insulating layer 16, the second insulating layer 36, and one second pad 40. The uppermost ends of the air gaps AG may be located at a level higher than the first interface IF1 between the first insulating layer 16 and the second insulating layer 36 and the second interface IF2 between the first pads 20 and the second pads 40. The lowermost ends of the air gaps AG may be located at the same level as the first interface IF1 between the first insulating layer 16 and the second insulating layer 36 and the second interface IF2 between the first pads 20 and the second pads 40.

Referring to FIG. 7, the first recesses RS1 may be provided on the first insulating layer 16. Each of the first recesses RS1 may surround one first pad 20. That is, when viewed in a plan view, each of the first recesses RS1 may have a planar shape of a ring surrounding each of the first pads 20, respectively. Each of the first recesses RS1 may expand to the first substrate 12 from the upper surface of the first insulating layer 16. In this case, the depth (e.g., the depth in the vertical direction) of each of the first recesses RS1 may decrease as the distance from each of the first pads 20 increases.

The second recesses RS2 (refer to FIG. 4) may not be provided on the second insulating layer 36. For example, the lower surfaces of the second pads 40 and the lower surface of the second insulating layer 36 may be in contact with each other.

The upper structure 30 may be disposed on the lower structure 10. The first pads 20 of the lower structure 10 and the second pads 40 of the upper structure 30 may be vertically aligned. The lower structure 10 and the upper structure 30 may be in contact with each other such that the first pads 20 and the second pads 40 are connected to each other.

At the interface between the lower structure 10 and the upper structure 30, the first insulating layer 16 of the lower structure 10 and the second insulating layer 36 of the upper structure 30 may be bonded. At the interface between the lower structure 10 and the upper structure 30, the first pads 20 of the lower structure 10 and the second pads 40 of the upper structure 30 may be bonded.

As the lower structure 10 and the upper structure 30 are bonded, the first recesses RS1 of the lower structure 10 may be disposed on the second insulating layer 36 of the upper structure 30. At the interface between the lower structure 10 and the upper structure 30, one first recess RS1 may constitute one air gap AG. That is, the air gaps AG may be empty spaces, each which is defined by the first insulating layer 16, the second insulating layer 36, and one first pad 20. The uppermost ends of the air gaps AG may be located the same level as the first interface IF1 between the first insulating layer 16 and the second insulating layer 36 and the second interface IF2 between the first pads 20 and the second pads 40. The lowermost ends of the air gaps AG may be located at a level lower than the first interface IF1 between the first insulating layer 16 and the second insulating layer 36 and the second interface IF2 between the first pads 20 and the second pads 40.

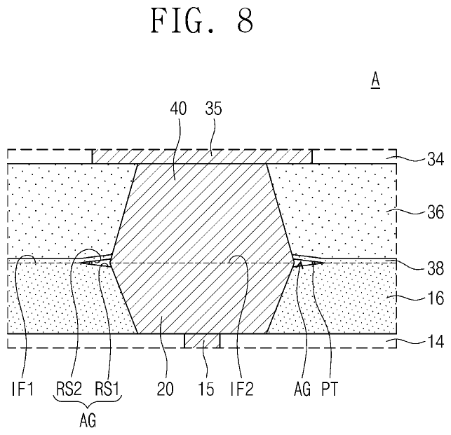

FIG. 8 is another enlarged view of the portion “A” of FIG. 1.

Referring to FIG. 8, the upper structure 30 may further include an upper passivation layer 38. The upper passivation layer 38 may conformally cover the second insulating layer 36 on the lower surface of the second insulating layer 36. For example, the upper passivation layer 38 may cover the lower surface of the second insulating layer 36 and a bottom surface of the second recess RS2. In some embodiments, the upper passivation layer 38 may have a uniform thickness along the lower surface of the second insulating layer 36 and the bottom surface of the second recess RS2, as illustrated in FIG. 8. The upper passivation layer 38 may expose the second pads 40. The upper passivation layer 38 may include the same material as the first insulating layer 16. The upper passivation layer 38 may include an insulating material such as silicon oxide (SiO), silicon nitride (SiN), silicon oxynitride (SiON), or silicon carbonitride (SiCN). The second insulating layer 36 may include the same material as the first insulating layer 16 or a different material.

At the interface between the lower structure 10 and the upper structure 30, the first insulating layer 16 of the lower structure 10 and the upper passivation layer 38 of the upper structure 30 may be bonded. In this case, the first insulating layer 16 and the upper passivation layer 38 may form oxide, nitride, or oxynitride hybrid bonding. For example, the first insulating layer 16 and the upper passivation layer 38 bonded to each other may have a continuous configuration, and the first interface IF1 between the first insulating layer 16 and the upper passivation layer 38 may not be visible. For example, the first insulating layer 16 and the upper passivation layer 38 may be formed of the same material, and thus there may be no interface between the first insulating layer 16 and the upper passivation layer 38. That is, the first insulating layer 16 and the upper passivation layer 38 may be provided as one component. For example, the first insulating layer 16 and the upper passivation layer 38 may be combined to form an integral one-piece (e.g., a monolithic or unitary layer).

At the interface between the lower structure 10 and the upper structure 30, the first pads 20 of the lower structure 10 and the second pads 40 of the upper structure 30 may be bonded.

As the lower structure 10 and the upper structure 30 are bonded, the first recesses RS1 of the lower structure 10 and the second recesses RS2 of the upper structure 30 may be connected to each other. At the interface between the lower structure 10 and the upper structure 30, the first recesses RS1 and the second recesses RS2 may be in contact with each other, and one first recess RS1 and one second recess RS2 may constitute one air gap AG. That is, the air gaps AG may be empty spaces, each which is defined by the first insulating layer 16, the upper passivation layer 38, the second insulating layer 36, one first pad 20, and/or one second pad 40. In some embodiments, each of the air gaps AG may be defined by the first insulating layer 16, the upper passivation layer 38, one first pad 20, and one second pad 40, as illustrated in FIG. 8.

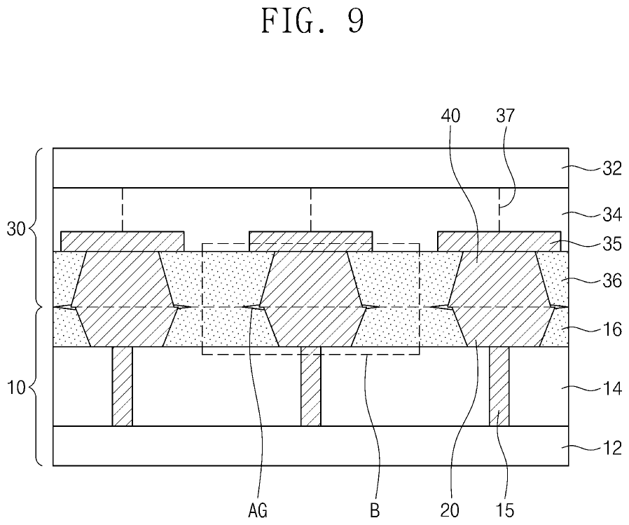

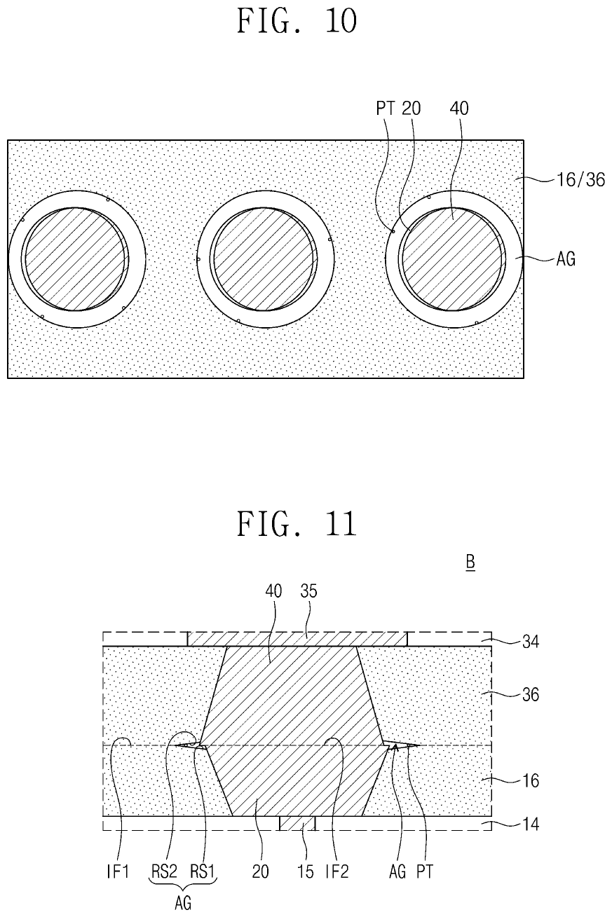

FIG. 9 is a cross-sectional view of a semiconductor device according to embodiments of the present inventive concept. FIG. 10 is a plan view of a semiconductor device according to embodiments. FIG. 11 is an enlarged view of the portion “B” of FIG. 9.

Referring to FIGS. 9 to 11, the upper structure 30 may be disposed on the lower structure 10. The first pads 20 and the second pads 40 may be stacked in a vertical direction. Here, the first pads 20 of the lower structure 10 and the second pads 40 of the upper structure 30 may be partially aligned vertically. For example, the first pads 20 and the second pads 40 may be shifted to each other in a horizontal direction. In some embodiments, a center of the first pad 20 in a horizontal direction may not be aligned with a center of the second pad 40 in the horizontal direction and may be offset from the center of the second pad 40 in the horizontal direction, as illustrated in FIGS. 9-11. Also, the first recesses RS1 of the lower structure 10 and the second recesses RS2 of the upper structure 30 may be partially vertically aligned. The lower structure 10 and the upper structure 30 may be in contact with each other such that the first pads 20 and the second pads 40 are connected to each other.

At the interface between the lower structure 10 and the upper structure 30, the first insulating layer 16 of the lower structure 10 and the second insulating layer 36 of the upper structure 30 may be bonded. At the interface between the lower structure 10 and the upper structure 30, the first pads 20 of the lower structure 10 and the second pads 40 of the upper structure 30 may be bonded.

As the lower structure 10 and the upper structure 30 are bonded, the first recesses RS1 of the lower structure 10 and the second recesses RS2 of the upper structure 30 may be connected to each other. In detail, the first recesses RS1 and the second recesses RS2 may at least partially overlap each other, the first recesses RS1 and the second recesses RS2 may be connected to each other. One first recess RS1 and one second recess RS2 into contacting with each other may constitute one air gap AG. That is, the air gaps AG may be empty spaces, each which is defined by the first insulating layer 16, the second insulating layer 36, one first pad 20, and one second pad 40. A distance from the side surface 20a (refer to FIG. 4) of the first pad 20 or the side surface 40a (refer to FIG. 4) of the second pad 40 to the outermost surface of the air gaps AG may be 0.1 μm to 5 μm.

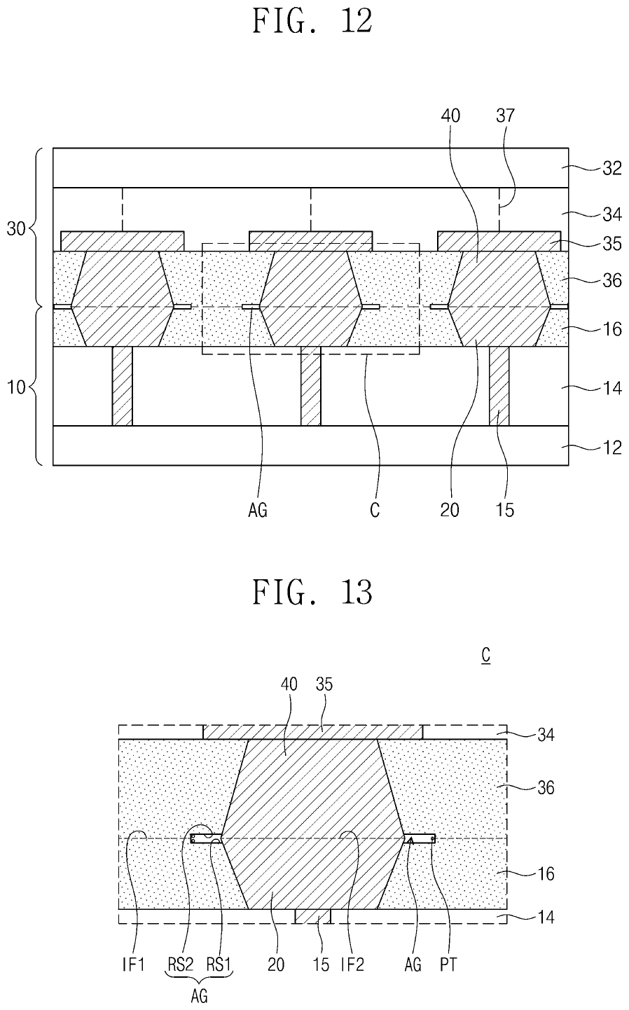

FIG. 12 is a cross-sectional view of a semiconductor device according to embodiments of the present inventive concept. FIG. 13 is an enlarged view of the portion “C” of FIG. 12.

Referring to FIGS. 12 and 13, the first recesses RS1 may be provided on the first insulating layer 16. Each of the first recesses RS1 may surround one first pad 20. The first recesses RS1 may expand to the first substrate 12 from the upper surface of the first insulating layer 16. In this case, the first depth of each of the first recesses RS1 may be uniform as a distance from each of the first pads 20 increases horizontally. That is, the vertical cross-section of each of the first recesses RS1 may be tetragonal.

The second recesses RS2 may be provided on the second insulating layer 36. Each of the second recesses RS2 may surround one second pad 40. The second recesses RS2 may expand to the second substrate 32 from the lower surface of the second insulating layer 36. In this case, the second depth of each of the second recesses RS2 may be uniform as a distance from each of the second pads 40 increases horizontally. That is, the vertical cross-section of each of the second recesses RS2 may be tetragonal.

The upper structure 30 may be disposed on the lower structure 10. At the interface between the lower structure 10 and the upper structure 30, the first insulating layer 16 of the lower structure 10 and the second insulating layer 36 of the upper structure 30 may be bonded. At the interface between the lower structure 10 and the upper structure 30, the first pads 20 of the lower structure 10 and the second pads 40 of the upper structure 30 may be bonded.

As the lower structure 10 and the upper structure 30 are bonded, the first recesses RS1 of the lower structure 10 and the second recesses RS2 of the upper structure 30 may be connected to each other. At the interface between the lower structure 10 and the upper structure 30, the first recesses RS1 and the second recesses RS2 may be in contact with each other, and one first recess RS1 and one second recess RS2 may constitute one air gap AG. That is, the air gaps AG may be empty spaces, each which is defined by the first insulating layer 16, the second insulating layer 36, one first pad 20, and one second pad 40. The first regions (e.g., the first regions R1 in FIG. 5) described above may correspond to regions in which the air gaps AG are provided. The uppermost ends of the air gaps AG may be located at a level higher than the first interface IF1 between the first insulating layer 16 and the second insulating layer 36 and the second interface IF2 between the first pads 20 and the second pads 40. The lowermost ends of the air gaps AG may be located at a level lower than the first interface IF1 between the first insulating layer 16 and the second insulating layer 36 and the second interface IF2 between the first pads 20 and the second pads 40. The width of each of the air gaps AG may be uniform as a distance from each of the first pads 20 and each of the second pads 40 increases. That is, the vertical cross-section of each of the air gaps AG may be tetragonal.

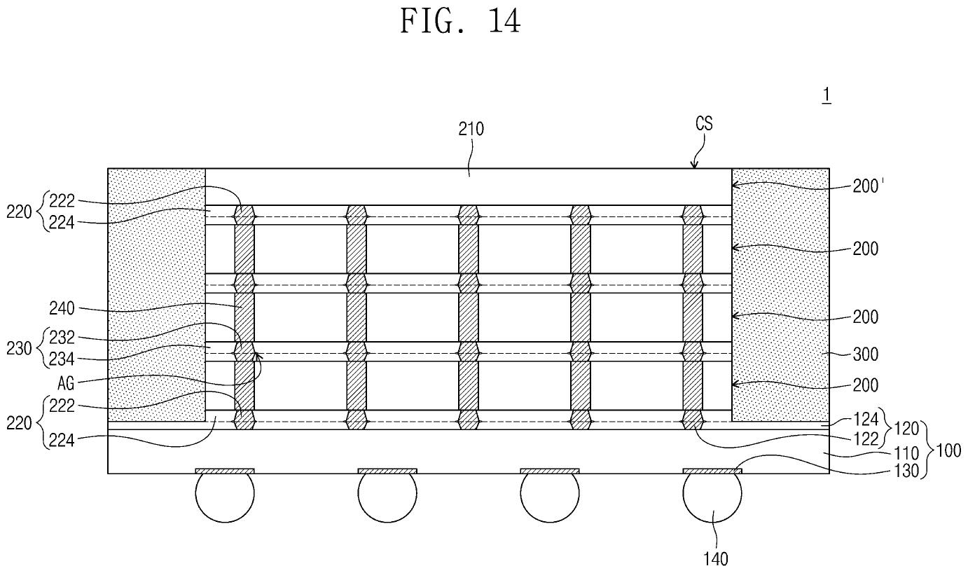

FIG. 14 is a cross-sectional view of a semiconductor device according to embodiments of the present inventive concept.

Referring to FIG. 14, a substrate 100 may be provided. The substrate 100 may be, for example, a substrate for a package, such as a printed circuit board (PCB), or an interposer substrate provided in the package. In some embodiments, the substrate 100 may be a semiconductor substrate on which semiconductor elements are formed or integrated. The substrate 100 may include a substrate base layer 110 and a substrate wiring layer 120 formed on the substrate base layer 110.

The substrate wiring layer 120 may include first substrate pads 120 exposed by an upper surface of the substrate base layer 110 and a substrate passivation layer 124 covering the substrate base layer 110 and surrounding the first substrate pads 122. In this case, upper surfaces of the first substrate pads 122 may be coplanar with an upper surface of the substrate passivation layer 124. Second substrate pads 130 exposed on a lower surface of the substrate base layer 110 may be provided. The substrate 100 may redistribute a chip stack CS, which will be described later. For example, the first substrate pads 122 and the second substrate pads 130 may be electrically connected by circuit wiring in the substrate base layer 110, and may constitute a redistribution circuit together with the circuit wiring. The first substrate pads 122 and the second substrate pads 130 may include a conductive material such as metal. For example, the first substrate pads 122 and the second substrate pads 130 may include copper (Cu). The substrate passivation layer 124 may include an insulating material such as oxide, nitride, or oxynitride of a material constituting the substrate base layer 110. For example, the substrate passivation layer 124 may include silicon oxide (SiO), silicon nitride (SiN), or silicon oxynitride (SiON).

Substrate connection terminals 140 may be disposed on the lower surface of the substrate 100. The substrate connection terminals 140 may be provided on the second substrate pads 130 of the substrate 100, respectively. The substrate connection terminals 140 may include, for example, a solder ball or a solder bump. According to the type and arrangement of the substrate connection terminals 140, a semiconductor device 1 may be provided in a form of a ball grid array (BGA), a fine ball grid array (FBGA), or a land grid array (LGA).

The chip stack CS may be disposed on the substrate 100. The chip stack CS may include at least one semiconductor chips 200 and 200′ stacked on the substrate 100. Each of the semiconductor chips 200 and 200′ may be a memory chip such as DRAM, SRAM, MRAM, or flash memory. In some embodiments, each of the semiconductor chips 200 and 200′ may be a logic chip. FIG. 14 illustrates that one chip stack CS is provided, but the present inventive concept is not limited thereto. When a plurality of chip stacks CS are provided, the chip stacks CS may be spaced apart from each other on the substrate 100.

One semiconductor chip 200 may be mounted on the substrate 100. The semiconductor chip 200 may include a semiconductor material such as silicon (Si).

The semiconductor chip 200 may include a chip base layer 210, a first chip wiring layer 220 disposed on a front surface of the semiconductor chip 200 based on the chip base layer 210, and a second chip wiring layer 230 disposed on a rear surface of the semiconductor chip 200 based on the chip base layer 210. Hereinafter, in the present specification, the front surface which is an active surface of an integrated element in the semiconductor chip, may be defined as a surface on which pads of the semiconductor chip are formed, and the rear surface may be defined a surface opposite to the front surface.

The first chip wiring layer 220 may include first chip pads 222 on the chip base layer 210 and first chip passivation layer 224 on the chip base layer 210 surrounding the first chap pads 222. The first chip pads 222 may be electrically connected to an integrated element or integrated circuits in the semiconductor chip 200. In some embodiments, wirings for redistribution may be provided between the first chip pads 222 and the integrated element in the semiconductor chip 200. The first chip pads 222 may include a conductive material such as metal. For example, the first chip pads 222 may include copper (Cu). The first chip passivation layer 224 may include an insulating material. For example, the first chip passivation layer 224 may include silicon oxide (SiO), silicon nitride (SiN), or silicon oxynitride (SiON).

The second chip wiring layer 230 may include second chip pads 232 on the chip base layer 210 and a second chip passivation layer 234 on the chip base layer 210 surrounding the second chip pads 232. The second chip pads 232 may be electrically connected to the first chip wiring layer 220. In some embodiments, the second chip pads 232 may be connected to the first chip wiring layer 220 via through electrodes 240 penetrating the chip base layer 210 vertically. The second chip pads 232 may include a conductive material such as metal. For example, the second chip pads 232 may include copper (Cu). The second chip passivation layer 234 may include an insulating material. For example, the second chip passivation layer 234 may include silicon oxide (SiO), silicon nitride (SiN), or silicon oxynitride (SiON).

The semiconductor chip 200 may be mounted on the substrate 100. As illustrated in FIG. 14, the front surface of the semiconductor chip 200 may face the substrate 100, and the semiconductor chip 200 may be electrically connected to the substrate 100. In this case, the front surface of the semiconductor chip 200, that is, a lower surface of the first chip wiring layer 220 may be in contact with the upper surface of the substrate 100. For example, the first chip pads 222 of the semiconductor chip 200 may be in contact with the first substrate pads 122 of the substrate 100, and the first chip passivation layer 224 may be in contact with the substrate passivation layer 124.

A plurality of semiconductor chips 200 may be provided. For example, another semiconductor chip 200 may be mounted on the one semiconductor chip 200. A front surface of the other semiconductor chip 200 may face the one semiconductor chip 200. In this case, the front surface of the other semiconductor chip 200 may be in contact with a rear surface of the one semiconductor chip 200. For example, a first chip wiring layer 220 of the other semiconductor chip 200 and the second chip wiring layer 230 of the one semiconductor chip 200 may be in contact with each other. In detail, the semiconductor chips 200 may be stacked such that the first chip passivation layer 224 and the second chip passivation layer 234 are in contact with each other, and the first chip pads 222 and the second chip pads 232 are in contact with each other.

The second chip pads 232 may correspond to the first pads 20 described with reference to FIGS. 1 to 13, and the first chip pads 222 may correspond to the second pads 40 described with reference FIGS. 1 to 13. For example, the first chip pads 222 and the second chip pads 232 may be bonded to each other, and the first chip passivation layer 224 and the second chip passivation layer 234 may be bonded to each other. The first chip pads 222 and the second chip pads 232 may form intermetallic hybrid bonding with each other. The first chip passivation layer 224 and the second chip passivation layer 234 may form hybrid bonding with each other. In this case, air gaps AG adjacent to the first chip pads 222 and the second chip pads 232 may be provided at an interface between the first chip passivation layer 224 and the second chip passivation layer 234. Although not shown in FIG. 14, metal particles PT (refer to FIGS. 1 to 13) may be disposed in the air gaps AG. The semiconductor chips 200 may be electrically connected to each other through the first chip pads 222 and the second chip pads 232. As described above, a plurality of semiconductor chips 200 and 200′ may be stacked on the substrate 100.

A configuration of the semiconductor chip 200′ provided at the uppermost one of the semiconductor chips 200 and 200′ of the chip stack CS may be partially different from configuration of the other semiconductor chips 200. For example, the uppermost semiconductor chip 200′ may not include the second chip wiring layer 230 and the through electrodes 240.

A molding layer 300 may be provided on the substrate 100. The molding layer 300 may cover the upper surface of the substrate 100. The molding layer 300 may surround the chip stack CS. That is, the molding layer 300 may cover side surfaces of the semiconductor chips 200. The molding layer 300 may protect the chip stack CS. The molding layer 300 may include an insulating material. For example, the molding layer 300 may include an epoxy molding compound (EMC). Unlike the drawings, the molding layer 300 may be formed to cover the chip stack CS. That is, the molding layer 300 may cover the rear surface of the uppermost semiconductor chip 200′.

Although the semiconductor chips 200 are illustrated to be mounted on the substrate 100, the present inventive concept is not limited thereto. According to other embodiments, the semiconductor chips 200 may be mounted on a base semiconductor chip. The base semiconductor chip may be a wafer-level semiconductor substrate formed of a silicon semiconductor (e.g., a silicon wafer). The base semiconductor chip may include an integrated circuit. For example, the integrated circuit may be a memory circuit, a logic circuit, or a combination thereof.

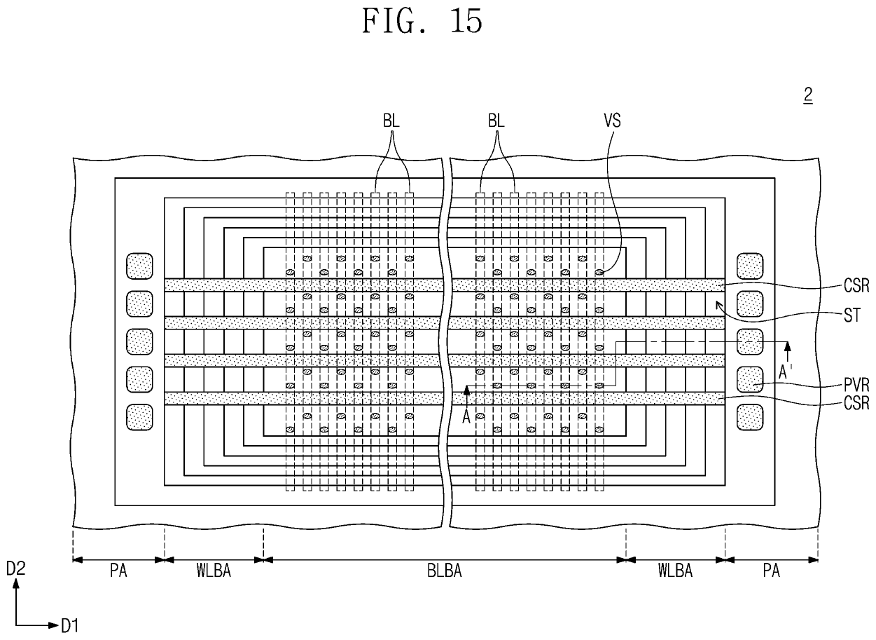

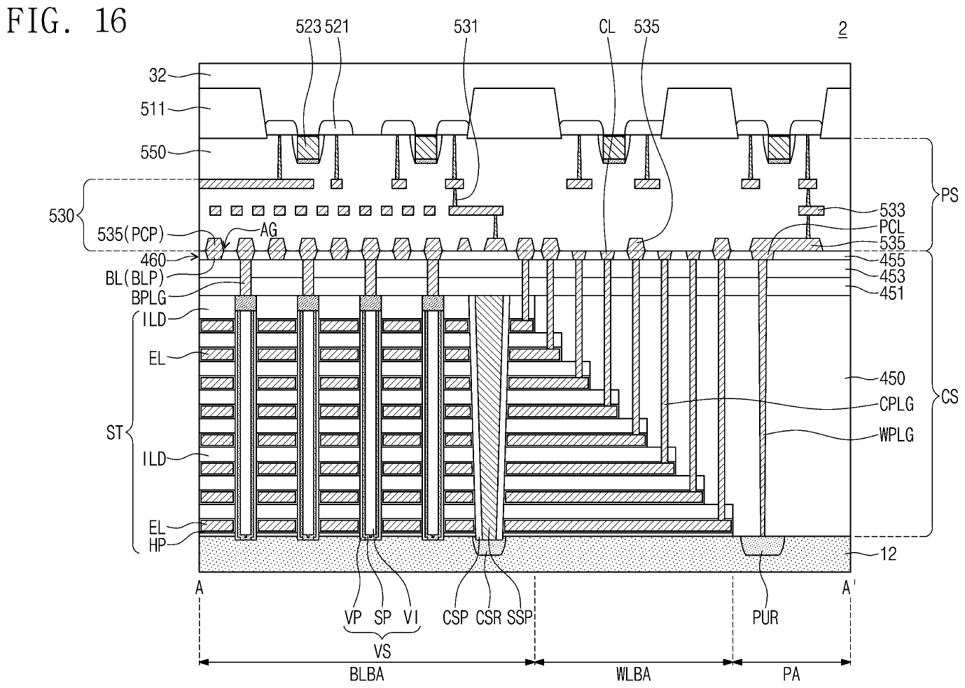

FIG. 15 is a plan view of a semiconductor device according to embodiments of the present inventive concept. FIG. 16 is a cross-sectional view of a semiconductor device according to embodiments of the present inventive concept, and corresponds to a cross-section taken along the line A-A′ of FIG. 15.

Referring to FIGS. 15 and 16, a semiconductor device may be a memory device. A semiconductor device 2 may have a chip to chip (C2C) structure. The C2C structure may be formed by forming an upper chip including a cell array structure CS on a first substrate (e.g., a first wafer), forming a lower chip including a peripheral circuit structure PS on a second substrate (e.g., a second wafer) different from the first substrate, and connecting the upper chip and the lower chip to each other by a bonding method. For example, the bonding method may refer to a method of electrically connecting a bonding metal formed in the uppermost metal layer of the upper chip and a bonding metal formed in the uppermost metal layer of the lower chip to each other. For example, when the bonding metal is formed of copper (Cu), the bonding method may be a Cu—Cu bonding method, and the bonding metal may be formed of aluminum or tungsten.

Each of the cell array structure CS and the peripheral circuit structure PS of the semiconductor device 2 may include an external pad bonding area PA, a word line bonding area WLBA, and a bit line bonding area BLBA.

A first substrate 12 may be provided. The first substrate 12 may be formed of a semiconductor material, for example, a silicon (Si) substrate, a silicon-germanium (Si—Ge) substrate, a germanium (Ge) substrate, or a single crystal epitaxy grown on a single crystal silicon substrate. For example, the first substrate 12 may be a silicon substrate (e.g., a silicon wafer). Also, the first substrate 12 may include a semiconductor doped with impurities of a first conductivity type (e.g., p-type) and/or an intrinsic semiconductor that is not doped with impurities.

According to embodiments, the cell array structure CS is provided on the first substrate 12, and includes stacked structures ST, vertical structures VS, and connection interconnection structures CPLG, CL, WPLG, and PCL. As an example, the first substrate 12 and the cell array structure CS may correspond to the lower structure 10 described with reference to FIG. 1, and a portion of the cell array structure CS may correspond to the first circuit layer 14 described with reference to FIG. 1.

The stacked structures ST may extend side by side in a first direction D1 on the first substrate 12 and may be arranged to be spaced apart from each other in a second direction D2. Each of the stacked structures ST includes electrodes EL and insulating layers ILD interposed therebetween, which are vertically stacked on the first substrate 12. A thickness of each of the insulating layers ILD in the stacked structures ST may vary depending on characteristics of the semiconductor memory device. For example, some of the insulating layers ILD may be formed to be thicker than other insulating layers ILD. The insulating layers ILD may include, for example, silicon oxide (SiO). The electrodes EL may include a conductive layer, for example, the conductive layer may include at least one of a semiconductor layer, a metal silicide layer, a metal layer, a metal nitride layer, or a multilayer layer including a combination thereof.

The stacked structures ST may extend from the bit line bonding area BLBA to the word line bonding area WLBA in the first direction D1, and may have a stepped structure in the word line bonding area WLBA. Lengths of the electrodes EL of the stack structures ST in the first direction D1 may decrease as a distance from the first substrate 12 increases. The stack structures ST may have various types of the stepped structure in the word line bonding area WLBA.

M embodiments, the semiconductor device may be a three-dimension NAND flash memory device, and cell strings may be integrated on the first substrate 12. In this case, in the stack structures ST, the lowermost and uppermost electrodes EL may be used as gate electrodes of selection transistors. For example, the uppermost electrode EL may be used as a gate electrode of a string select transistor that controls an electrical connection between a bit line BL and the vertical structures VS, and the lowermost electrode EL may be used as a gate electrode of a ground selection transistor that controls an electrical connection between a common source line and the vertical structures VS. In addition, the electrodes EL between the uppermost and lowermost electrodes EL may be used as control gate electrodes of the memory cells and word lines connecting the gate electrodes of the memory cells.

The vertical structures VS may pass through the stack structures ST in the bit line bonding area BLBA to be in contact with the first substrate 12. The vertical structures VS may be electrically connected to the first substrate 12. The vertical structures VS may be arranged in one direction or arranged in a zigzag form when viewed in a plan view. Furthermore, dummy vertical structures (not shown) having substantially the same structure as the vertical structures VS may be provided in the word line bonding area WLBA or the external pad bonding area PA.

The vertical structures VS may include a semiconductor material such as silicon (Si), germanium (Ge), or a mixture thereof. In addition, the vertical structures VS may be semiconductors doped with impurities or intrinsic semiconductors that are not doped with impurities. The vertical structures VS including semiconductor material may be used as channels of the select transistors and memory cell transistors. Bottom surfaces of the vertical structures VS may be positioned between an upper surface and a lower surface of the first substrate 12. A contact pad connected to a bit line contact plug BPLG may be positioned on top ends of the vertical structures VS.

Each of the vertical structures VS may include a semiconductor pattern SP and a vertical insulating pattern VP in contact with the first substrate 12. The semiconductor pattern SP may have a hollow pipe shape or a macaroni shape. A lower end of the semiconductor pattern SP may have a closed shape, and the inside of the semiconductor pattern SP may be filled by a buried insulating pattern VI. The semiconductor pattern SP may be in contact with the upper surface of the first substrate 12. The semiconductor pattern SP may be undoped or may be doped with impurities having the same conductivity type as those of the first substrate 12. The semiconductor pattern SP may be in a polycrystalline or a single crystal.

The vertical insulating pattern VP may be disposed between the stacked structure ST and the vertical structures VS. The vertical insulating pattern VP may extend in a third direction D3 and surround the sidewall of the vertical structure VS. That is, the vertical insulating pattern VP may be in a form of a pipe having upper and lower ends open, or in a form of macaroni. The vertical insulating pattern VP may be formed of one thin film or a plurality of thin films. In some embodiments of the present inventive concept, the vertical insulating pattern VP may be a part of a data storage layer. For example, the vertical insulating pattern VP may be a data storage layer of the NAND flash memory device, and may include a tunnel insulating layer, a charge storage layer, and a blocking insulating layer. For example, the charge storage layer may be a trap insulating layer, a floating gate electrode, or an insulating layer including conductive nano dots. In detail, the charge storage layer may include, for example, at least one of silicon nitride (SiN), silicon oxynitride (SiON), silicon-rich nitride, nanocrystalline silicon, and a laminated trap layer. The tunnel insulating layer may be one of materials having a band gap larger than that of the charge storage layer, and the blocking insulating layer may be a high-k material such as aluminum oxide (Al₂O₃) and hafnium oxide (Hf₂O). In some embodiments, the vertical insulating layer may include a thin film for a phase change memory or a thin film for a variable resistance memory.

A horizontal insulating pattern HP may be provided between one sidewalls of the electrodes EL and the vertical insulating pattern VP. The horizontal insulating pattern HP may extend from one sidewalls of the electrodes EL to upper and lower surfaces of the electrodes EL. The horizontal insulating pattern HP may include the charge storage layer and the blocking insulating layer as a part of the data storage layer of the NAND flash memory device. In some embodiments, the horizontal insulating pattern HP may include the blocking insulating layer.

Common source regions CSR may be respectively disposed in the first substrate 12 between the stacked structures ST adjacent to each other. The common source regions CSR may extend in the first direction D1 in parallel to the stack structures ST. The common source regions CSR may be formed by doping impurities of a second conductivity type into the first substrate 12. The common source regions CSR may include, for example, N-type impurities (e.g., arsenic (As) or phosphorus (P)).

A common source plug CSP may be connected to the common source region CSR. A sidewall insulating spacer SSP may be interposed between the common source plug CSP and the stacked structures ST. A ground voltage may be applied to the common source region CSR through the common source plug CSP during a read or program operation of the three-dimension NAND flash memory device.

A first buried insulating layer 450 may be disposed on the first substrate 12 to cover ends of the electrodes EL having a stepped structure. A first interlayer insulating layer 451 may cover upper surfaces of the vertical structures VS, and a second interlayer insulating layer 453 may cover the upper surface of the common source plug CSP on the first interlayer insulating layer 451.

The bit lines BL may be disposed on the second interlayer insulating layer 453 and extend in the second direction D2 across the stack structures ST. The bit lines BL may be electrically connected to the vertical structure VS through the bit line contact plug BPLG. The bit lines BL may correspond to pads for electrical connection with the peripheral circuit structure PS, which will be described later. The bit lines BL may have bit line pads BLP. The bit line pads BLP may be similar to or the same as the first pads 20 described with reference to FIGS. 1 to 13.

A connection wiring structure for electrically connecting the cell array structure CS and the peripheral circuit structure PS may be disposed at the ends of the stacked structures ST having the stepped structure. The connection wiring structure includes the cell contact plugs CPLG that pass through the first buried insulating layer 450 and the first and second interlayer insulating layers 451 and 453 and are respectively connected to ends of the electrodes EL, and the connection lines CL respectively connected to cell contact plugs CPLG on the second interlayer insulating layer 453. In addition, the connection wiring structure may include well contact plugs WPLG connected to well pickup regions PUR in the first substrate 12, and the peripheral connection lines PCL connected to the well contact plugs WPLG. The bit lines BL, the connection lines CL, and the peripheral connection lines PCL may constitute a cell array wiring layer 460.

The well pickup regions PUR may be disposed adjacent to both ends of each of the stack structures ST in the first substrate 12. The well pickup regions PUR may have the same conductivity type as that of the first substrate 12, and an impurity concentration in the well pickup regions PUR may be higher than an impurity concentration in the first substrate 12. For example, the well pickup regions PUR may include a high concentration of p-type impurities (e.g., boron (B)). In embodiments, an erase voltage may be applied to the well pickup regions PUR through the well contact plug WPLG during an erase operation of the three-dimension NAND flash memory device.

A third interlayer insulating layer 455 may surround the bit lines BL, the connection lines CL, and the peripheral connection lines PCL on the second interlayer insulating layer 453. Upper surfaces of the bit line pads BLP, upper surfaces of the connection lines CL, and upper surfaces of the peripheral connection lines PCL may be exposed by the third interlayer insulating layer 455. The third interlayer insulating layer 455 may be the same as or similar to the first insulating layer 16 described with reference to FIGS. 1 to 13. The bit lines BL, the connection lines CL, and the peripheral connection lines PCL may constitute the cell array wiring layer 460. The bit lines BL, the connection lines CL, and the peripheral connection lines PCL may correspond to pads of the cell array structure CS electrically connected to the peripheral circuit structure PS to be described later.

As described above, the cell array structure CS may be disposed on the first substrate 12.

The peripheral circuit structure PS may be disposed on the cell array structure CS.

A second substrate 32 may be provided. The second substrate 32 may be a silicon substrate, a silicon-germanium substrate, a germanium substrate, or a single crystal epitaxial layer grown on a single crystal silicon substrate. For example, the second substrate 32 may be a silicon substrate having a first conductivity type (e.g., p-type) and may include well regions.

The peripheral circuit structure PS may include peripheral circuits integrated on the entire surface of the second substrate 32, and a second buried insulating layer 550 covering the peripheral circuits. As an example, the second substrate 32 and the peripheral circuit structure PS may correspond to the upper structure 30 described with reference to FIG. 1, and a part of the peripheral circuit structure PS may correspond to the second circuit layer 34.

The peripheral circuits may be row and column decoders, a page buffer, and a control circuit, and may include NMOS and PMOS transistors, low and high voltage transistors, and resistors integrated on one side of the second substrate 32. In detail, the peripheral circuits may include a pre-charge control circuit for controlling a plurality of data programming steps for a plurality of memory cells and controlling some cell strings among the plurality of cell strings. In detail, active regions may be defined by a device isolation layer 511 formed in the second substrate 32. Peripheral gate electrodes 523 may be disposed on the second substrate 32 of the active region with a gate insulating layer interposed therebetween. Source/drain regions 521 may be provided in the second substrate 32 on both sides of the peripheral gate electrodes 523.

Peripheral circuit wiring layer 530 may be connected to the peripheral circuits on the second substrate 32. The peripheral circuit wiring layer 530 may include peripheral circuit wirings 533 and peripheral circuit contact plugs 531. The peripheral circuit wirings 533 may be electrically connected to the peripheral circuits through peripheral circuit contact plugs 531. For example, the peripheral circuit plugs 531 and the peripheral circuit wirings 533 may be connected to the NMOS and PMOS transistors.

The second buried insulating layer 550 may cover the peripheral gate electrodes 523, the peripheral circuit plugs 531, and the peripheral circuit wirings 533. The second buried insulating layer 550 may further include exposed wirings 535 exposed on the lower surface of the second buried insulating layer 550 in the peripheral circuit wiring layer 530. The exposed wirings 535 may correspond to pads for electrically connecting the peripheral circuit structures PS to the cell array structure CS. The exposed wirings 535 may have peripheral circuit pads PCP. The peripheral circuit pads PCP may be similar to or the same as the second pads 40 described with reference to FIGS. 1 to 13. For example, a width of each of the peripheral circuit pads PCP may be smaller than a width of each of the bit line pads BLP, and a thickness of each of the peripheral circuit pads PCP may be greater than a thickness of each of the bit line pads BLP. The second buried insulating layer 550 may include insulating layers stacked in multiple layers. For example, the second buried insulating layer 550 may include silicon oxide (SiO), silicon nitride (SiN), silicon oxynitride (SiON), and/or a low-k material. In some embodiments, the peripheral circuit wirings 533 and the peripheral circuit contact plugs 531 may be formed of tungsten having a relatively high resistance, and the exposed wirings 535 may be formed of copper having a relatively low resistance.

In present specification, only one layer of peripheral circuit wirings 533 is shown and described, but the present inventive concept is not limited thereto. A plurality of peripheral circuit wirings 533 may be provided and stacked on each other. In this case, at least a portion of the plurality of peripheral circuit wirings 533 may be formed of, for example, aluminum having a lower resistance than copper forming the exposed wirings 535.

The cell array structure CS and the peripheral circuit structure PS may be in direct contact with each other. For example, as shown in FIG. 16, the cell array wiring layer 460 of the cell array structure CS and the peripheral circuit wiring layer 530 of the peripheral circuit structure PS may be in contact with each other. For example, the third interlayer insulating layer 455 and the second filling insulating layer 550 may be in contact with each other, and at least some of the bit lines BL, the connection lines CL, and the peripheral connection lines PCL may be connected to the exposed wirings 535. In this case, the cell array wiring layer 460 and the peripheral circuit wiring layer 530 may form an intermetallic hybrid bonding. The bit line pads BLP and the exposed wirings 535 may have a continuous configuration, and an interface between the bit line pads BLP and the exposed wirings 535 may not be visible. For example, as the bit line pads BLP and the exposed wirings 535 are formed of the same material, there may be no interface between the bit line pads BLP and the exposed wirings 535. That is, the bit line pad BLP and the exposed wiring 535 corresponding to each other may be provided as one component. The third interlayer insulating layer 455 and the second buried insulating layer 550 may be bonded to each other. The third interlayer insulating layer 455 and the second buried insulating layer 550 may form a hybrid bonding with each other. In this case, air gaps AG adjacent to the bit line pads BLP and the exposed wirings 535 may be provided on an interface between the third interlayer insulating layer 455 and the second buried insulating layer 550. Although not shown in FIG. 16, metal particles PT (refer to FIGS. 1 to 13) may be disposed in the air gaps AG.

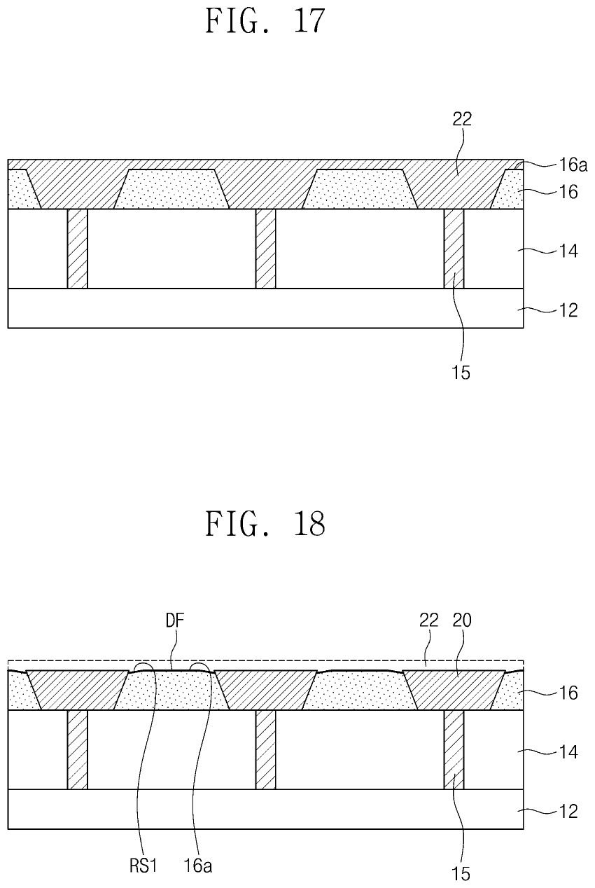

FIGS. 17 to 23 are cross-sectional views illustrating a method of fabricating a semiconductor device according to embodiments of the present inventive concept.

Referring to FIG. 17, a first substrate 12 may be provided. The first substrate 12 may be a semiconductor substrate. A first circuit layer 14 may be formed on the first substrate 12. The first circuit layer 14 may have a first connection wiring 15 for connecting the first substrate 12 and first pads 20 (refer to FIG. 18). A first insulating layer 16 may be formed by depositing an insulating material on the first circuit layer 14. Holes for providing the first pads 20 may be formed by patterning the first insulating layer 16. A first conductive layer 22 filling the holes may be formed on the first insulating layer 16. The forming of the first conductive layer 22 may include a plating process using a seed layer. The first conductive layer 22 may cover an upper surface 16a of the first insulating layer 16.

Referring to FIG. 18, a first planarization process may be performed on the first conductive layer 22. An upper portion of the first conductive layer 22 may be removed by the first planarization process to form first pads 20. The upper surface 16a of the first insulating layer 16 may be exposed. During the first planarization process, the first insulating layer 16 may be over-etched. For example, an etchant used in the first planarization process may have etching selectivity with respect to the first insulating layer 16. Accordingly, first recesses RS1 may be formed on the first insulating layer 16 adjacent to the first pads 20 having a hardness higher than that of the first insulating layer 16. A lower structure may be formed as described above.

During the first planarization process, a byproduct generated when the first conductive layer 22 is removed may be deposited on the first insulating layer 16. The byproduct may form a debris film DF covering the upper surface 16a of the first insulating layer 16 and a bottom surface of the first recesses RS1. The debris film DF may include the same material as the first conductive layer 22. For example, the debris film DF may include copper (Cu).

FIG. 18 illustrates that the first recesses RS1 are formed during the first planarization process, but the present inventive concept is not limited thereto. Referring to FIG. 19, the first recesses RS1 may not be formed during the first planarization process.

A first mask pattern MP1 may be formed on the first insulating layer 16. The first mask pattern MP1 may expose the first pads 20 and a portion of the first insulating layer 16 adjacent to the first pads 20. Thereafter, an etching process may be performed on the first insulating layer 16 to form the first recesses RS1. Thereafter, the first mask pattern MP1 may be removed.

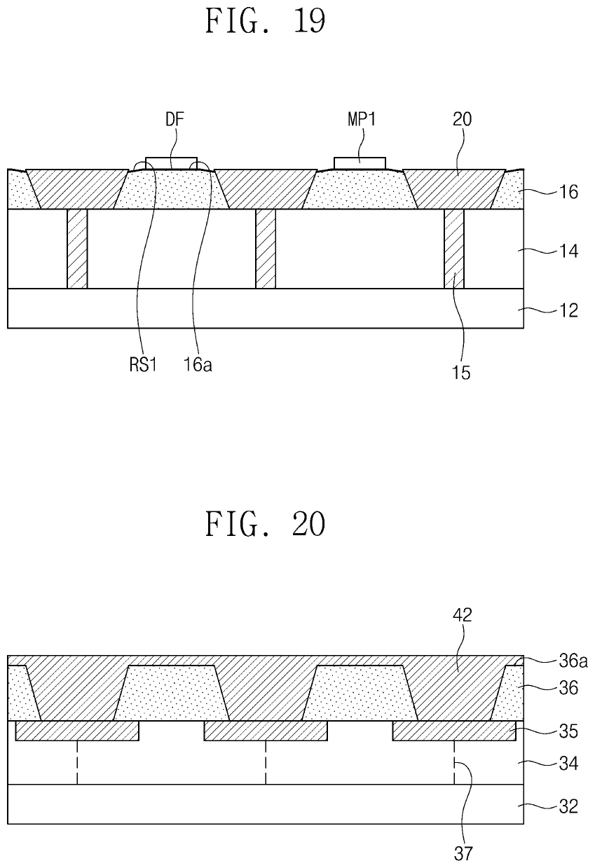

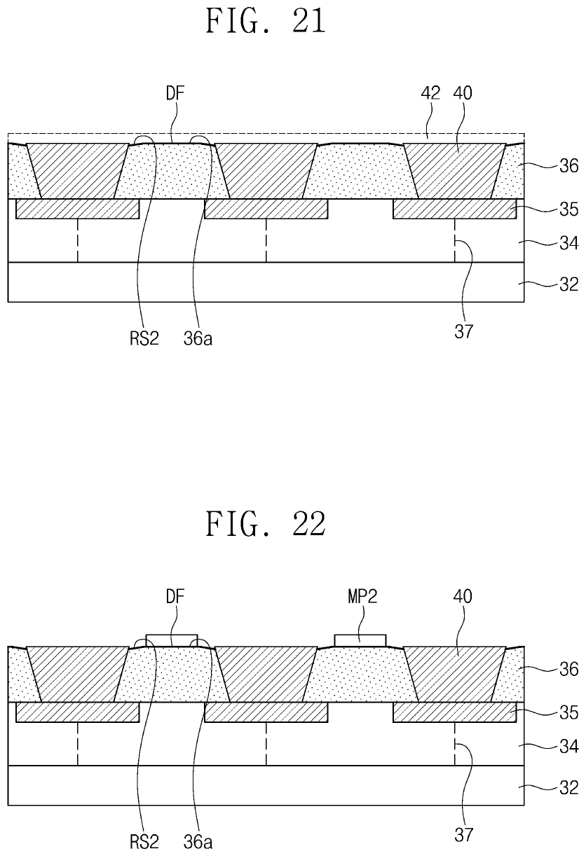

Referring to FIG. 20, a second substrate 32 may be provided. The second substrate 32 may be a semiconductor substrate. A second circuit layer 34 may be formed on the second substrate 32. A second insulating layer 36 may be formed by depositing an insulating material on the second circuit layer 34. Holes for providing second pads 40 (refer to FIG. 21) may be formed by patterning the second insulating layer 36. A second conductive layer 42 filling the holes may be formed on the second insulating layer 36. The forming of the second conductive layer 42 may include a plating process using a seed layer. The second conductive layer 42 may cover an upper surface 36a of the second insulating layer 36.

Referring to FIG. 21, a second planarization process may be performed on the second conductive layer 42. An upper portion of the second conductive layer 42 may be removed by the second planarization process to form the second pads 40. The upper surface 36a of the second insulating layer 36 may be exposed. During the second planarization process, the second insulating layer 36 may be over-etched. For example, an etchant used in the second planarization process may have etching selectivity with respect to the second insulating layer 36. Accordingly, second recesses RS2 may be formed on the second insulating layer 36 adjacent to the second pads 40 having a hardness higher than that of the second insulating layer 36. An upper structure may be formed as described above.

During the second planarization process, the second conductive layer 42 is removed and a byproduct generated may be deposited on the second insulating layer 36. The byproduct may form a debris film DF covering the upper surface 36a of the second insulating layer 36 and a bottom surface of the second recesses RS2. The debris film DF may include the same material as the second conductive layer 42. For example, the debris film DF may include copper (Cu).

FIG. 21 illustrates that the second recesses RS2 are formed during the second planarization process, but the present inventive concept is not limited thereto. Referring to FIG. 22, the second recesses RS2 may not be formed during the second planarization process.

A second mask pattern MP2 may be formed on the second insulating layer 36. The second mask pattern MP2 may expose the second pads 40 and a portion of the second insulating layer 36 adjacent to the second pads 40. Thereafter, an etching process may be performed on the second insulating layer 36 to form the second recesses RS2. Thereafter, the second mask pattern MP2 may be removed.

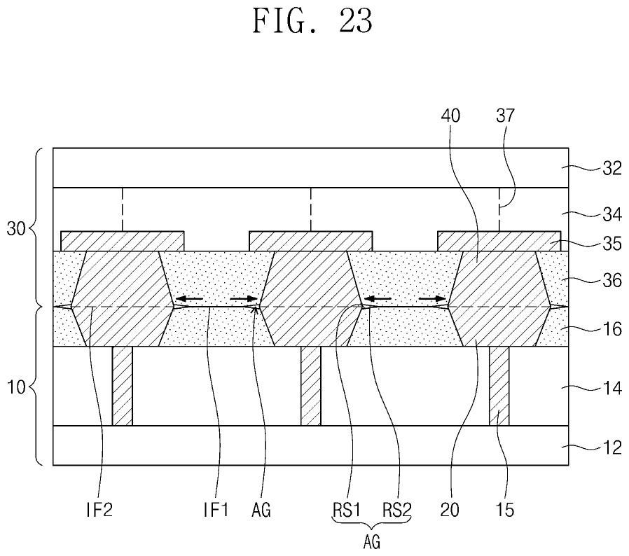

Referring to FIG. 23, the upper structure 30 may be provided on the lower structure 10. For example, the upper structure 30 may be disposed on the lower structure 10 such that the first pads 20 and the second pads 40 are vertically aligned.

Thereafter, the lower structure 10 and the upper structure 30 may be in contact with each other. The upper surface of the first insulating layer 16 and the lower surface of the second insulating layer 36 may be in contact with each other, and the upper surfaces of the first pads 20 and the lower surfaces of the second pads 40 may be in contact with each other. In this case, the first recesses RS1 and the second recesses RS2 may be connected to each other. The first recesses RS1 and the second recesses RS2 may constitute air gaps AG, respectively.

A heat treatment process may be performed on the lower structure 10 and the upper structure 30. The first pads 20 and the second pads 40 may be bonded to each other by the heat treatment process. For example, the first pads 20 may be combined with the second pads 40 to form an integral one-piece (e.g., a monolithic or unitary layer). A coupling of the first pads 20 and the second pads 40 may naturally proceed. In detail, the first pads 20 and the second pads 40 may be formed of the same material (e.g., copper (Cu)), and the surrounding first pads 20 and the second pads 40 may be combined using intermetallic hybrid bonding by surface activation at a first interface IF1 of the first pads 20 and the second pads 40 in contact with each other. The first insulating layer 16 and the second insulating layer 36 may be bonded to each other by the heat treatment process.

During the heat treatment process, a metal material (e.g., metal particles) in the debris film DF interposed between the first insulating layer 16 and the second insulating layer 36 may move along the first insulating layer 16 and the second insulating layer 16. In detail, as shown by an arrow in FIG. 23, the metal material in the debris film DF may move toward the air gaps AG. The metal materials collected in the air gaps AG may form metal particles PT (refer to FIG. 4).

According to embodiments of the present inventive concept, the debris between the first insulating layer 16 and the second insulating layer 36 may be collected into the air gaps AG. Accordingly, the debris film DF existing along the interface between the first insulating layer 16 and the second insulating layer 36 may be removed, and an electrical short path present at the interface between the first insulating layer 16 and the second insulating layer 36 may be removed. That is, the method of fabricating the semiconductor device with less defects may be provided.

The terms “first,” “second,” “third,” etc., may be used herein merely to distinguish one element from another. As used herein the term “and/or” includes any and all combinations of one or more of the associated listed items. Further, as used herein, an element or region that is “covering” or “surrounding” or “filling” another element or region may completely or partially cover or surround or fill the other element or region.

In the semiconductor device according to the embodiments of the present inventive concept, the short circuit occurring between the adjacent pads due to the debris remaining between the insulating layers may be reduced or absent. That is, the semiconductor device having the improved electrical characteristics and the improved driving stability may be provided.

The above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents and shall not be restricted or limited by the foregoing detailed Description.

1. A semiconductor device comprising:
a lower structure; and
an upper structure,
wherein the lower structure includes:
a first semiconductor substrate;
a first insulating layer on the first semiconductor substrate; and
a first pad including a portion that is in the first insulating layer, wherein the upper structure includes:
a second semiconductor substrate;
a second insulating layer on the second semiconductor substrate; and
a second pad including a portion that is in the second insulating layer,
wherein the first pad and the second pad are in contact with each other, and the first insulating layer and the second insulating layer are in contact with each other,
wherein the first insulating layer includes a first recess connected to the first pad,
wherein the second insulating layer includes a second recess that is connected to the second pad and overlaps the first recess, and
wherein the first recess and the second recess define a cavity that includes particles of a metallic material constituting the first and second pads.

2. The semiconductor device of claim 1, wherein the first recess extends around the first pad in plan view,
wherein the second recess extends around the second pad in plan view.

3. The semiconductor device of claim 1, wherein each of the first pad and the second pad has a circular shape or a quadrangular shape in plan view, and
wherein each of the first recess and the second recess has a circular ring shape or a quadrangular ring shape in plan view, the first recess is larger than the first pad in plan view, and the second recess is larger than the second pad in plan view.

4. The semiconductor device of claim 1, wherein the first pad and the second pad are stacked in a first direction, and
a widest width of the cavity in a second direction is from 0.1 μm to 5 μm, and the second direction is perpendicular to the first direction.

5. The semiconductor device of claim 1, wherein the metallic material includes copper (Cu), and
wherein the first insulating layer and the second insulating layer include an oxide, nitride, or oxynitride and include a material constituting the first and second semiconductor substrates.

6. The semiconductor device of claim 1, wherein an interface between the first insulating layer and the second insulating layer includes:
a first region adjacent to the cavity; and
a second region,
wherein the first region is between the cavity and the second region, and
a concentration of the metallic material in the first region is less than a concentration of the metallic material in the second region.

7. (canceled)

8. (canceled)

9. The semiconductor device of claim 1, wherein a depth of the first recess and a depth of the second recess decrease or remain constant as a distance from the first pad or the second pad increases.

10. (canceled)

11. The semiconductor device of claim 1, wherein the first pad and the second pad include the same material and collectively constitute a monolithic layer.

12. A semiconductor device comprising:
a lower structure including a first substrate, a first circuit pattern on the first substrate, a first insulating layer on the first circuit pattern, and a first pad that includes a metallic material, includes a portion not contacted by the first insulating layer and is electrically connected to the first circuit pattern;
an upper structure including a second substrate, a second circuit pattern on the second substrate, a second insulating layer on the second circuit pattern, and a second pad that includes the metallic material, includes a portion not contacted by the second insulating layer and is electrically connected to the second circuit pattern, wherein the upper structure contacts the lower structure; and
a cavity that extends around the first pad and the second pad in plan view and is defined by the first insulating layer and the second insulating layer,
wherein the second pad and the first pad contact each other, include the same material and collectively constitute a monolithic layer, and
wherein an interface between the first insulating layer and the second insulating layer includes:
a first region extending around the cavity; and
a second region,
wherein the first region is between the cavity and the second region, and
a concentration of the metallic material in the first region is less than a concentration of the metallic material in the second region.

13. The semiconductor device of claim 12, wherein particles of the metallic material constituting the first and second pads are in the cavity.

14. The semiconductor device of claim 13, wherein the particles of the metallic material are adjacent to a farthest portion of the cavity from the first pad and the second pad.

15-17. (canceled)

18. The semiconductor device of claim 12, wherein each of the first pad and the second pad has a circular shape or a quadrangular shape in plan view, and
wherein the cavity has a circular ring shape or a quadrangular ring shape in plan view, and the cavity is larger than the first and second pads in plan view.

19. The semiconductor device of claim 12, wherein the lower structure and the upper structure are stacked in a vertical direction, and
a widest width of the cavity in a horizontal direction is from 0.1 μm to 5 μm.

20. The semiconductor device of claim 12, wherein the metallic material includes copper (Cu), and
wherein the first insulating layer and the second insulating layer include an oxide, nitride, or oxynitride and include a material constituting the first and second substrates.

21. (canceled)

22. The semiconductor device of claim 12, wherein the lower structure and the upper structure are stacked in a vertical direction, and
a width of the cavity in a horizontal direction decreases or remains constant as a distance from the first pad or the second pad increases.

23-29. (canceled)

30. A semiconductor device comprising:
a substrate;
a substrate pad on an upper surface of the substrate;
a conductive pattern in contact with a lower surface of the substrate pad;
a first insulating layer and a second insulating layer stacked on the substrate, wherein the conductive pattern is in the first insulating layer and the second insulating layer; and
a semiconductor chip on the upper surface of the substrate,
wherein the semiconductor chip includes:
a semiconductor substrate;
a wiring layer that is on a lower surface of the semiconductor substrate and includes a wiring pattern; and
a bonding pad connected to a lower surface of the wiring pattern,
wherein the bonding pad contacts the substrate pad,
wherein the first insulating layer includes a first region and a second region, the first region extends around the conductive pattern and is between the conductive pattern and the second region,
wherein the first region of the first insulating layer is spaced apart from the second insulating layer, and the second region of the first insulating layer is in contact with the second insulating layer, and
wherein particles of a metallic material that constitutes the conductive pattern are between the first region of the first insulating layer and the second insulating layer.

31-33. (canceled)

34. The semiconductor device of claim 30, wherein a distance between the first region of the first insulating layer and the second insulating layer decreases or remains constant as a distance from the conductive pattern increases.

35. The semiconductor device of claim 30, wherein the conductive pattern is a monolithic layer.

36. The semiconductor device of claim 1, wherein the first recess encloses the first pad in plan view, and the second recess encloses the second pad in plan view.

37. The semiconductor device of claim 1, wherein an interface between the first insulating layer and the second insulating layer is spaced apart from the first and second pads.
